(19) United States
(12) Patent Application Publication
(10) Pub. No.: US 2022/0033684 A1
(43) Pub. Date: Feb. 3, 2022

(54) POLISHING LIQUID

(71) Applicant: DISCO CORPORATION, Tokyo (JP)

(72) Inventors: Ayumu SAKAI, Tokyo (JP); Norihisa ARIFUKU, Tokyo (JP); Takeshi SATO, Tokyo (JP)

(21) Appl. No.: 17/381,804

(22) Filed: Jul. 21, 2021

(30) Foreign Application Priority Data
Jul. 30, 2020 (JP) 2020-129207

(51) Int. Cl. C09G 1/04; B24B 37/04

(52) U.S. Cl. CPC C09G 1/04; H01L 21/30625; B24B 37/044

(57) ABSTRACT

Provided is a polishing liquid that is used when one surface of a wafer is polished by use of a fixed abrasive grain polishing pad with abrasive grains fixed in the pad, in which an organic salt that exhibits a basic property by hydrolysis and contains no metal and an organic base that contains no metal are dissolved, and no abrasive grains are contained. Preferably, the organic salt includes a strong basic cation and a weak acidic anion, and the organic base contains at least one of ammonia, an amine, and a basic amino acid.

### BACKGROUND OF THE INVENTION

### Field of the Invention

The present invention relates to a polishing liquid used when polishing a wafer.

### Description of the Related Art

Electronic equipment such as a mobile phone and a personal computer has device chips mounted thereon. The device chips are manufactured, for example, by processing a silicon wafer formed with devices such as integrated circuits (ICs) and large scale integration (LSI) circuits on the front surface side thereof. Specifically, first, the back surface side of the wafer is roughly ground by use of a grinding apparatus, and then, the back surface side is subjected to finish grinding, to thin the wafer to a predetermined thickness (see, for example, Japanese Patent Laid-open No. 2000-288881). In general, upon the grinding step, grinding marks (saw marks) are left on the grounded surface. After the grinding step, therefore, the back surface side of the wafer is polished by use of a chemical mechanical polishing (CMP) apparatus to remove the saw marks (see, for example, Japanese Patent Laid-open No. Hei 8-99265). After the polishing step, the wafer is divided into a plurality of device chips by use of a cutting apparatus.

One example of the polishing apparatus (of a face-down system in which the lower surface side of a wafer is polished) will be described. The polishing apparatus has a circular surface table which is rotatable around a rotational axis substantially parallel to the vertical direction. A disk-shaped polishing pad is fixed on an upper surface of the surface table. As the polishing pad, for example, a fixed abrasive grain polishing pad containing abrasive grains is used. In addition, a nozzle for supplying a polishing liquid is disposed above the fixed abrasive grain polishing pad. A disk-shaped carrier that is rotatable around a rotational axis substantially parallel to the vertical direction and is capable of holding the wafer under suction is disposed above the fixed abrasive grain polishing pad, in a region different from the region of the nozzle. To polish the wafer, first, the upper surface side of the wafer is held by a holding surface of the carrier. Then, a polishing liquid is supplied onto an upper surface of the fixed abrasive grain polishing pad being rotated, and at the same time, the lower surface side of the wafer is pressed against the upper surface of the fixed abrasive grain polishing pad while the wafer is rotated. By a chemical action and a mechanical action on the lower surface side of the wafer and the upper surface side of the fixed abrasive grain polishing pad including the polishing liquid, the lower surface side of the wafer is polished.

### SUMMARY OF THE INVENTION

As the polishing liquid, for example, an aqueous solution in which an inorganic salt exhibiting a basic property by hydrolysis is dissolved is used. However, the inorganic salt generally includes a weak acidic anion and a strong basic cation that is represented by the general formula: M(OH)ₙ (where M becomes a cation Mⁿ⁺, and n is an integer of equal to or more than 1). As the strong basic cation, a cation of an alkali metal such as potassium ion or sodium ion or a cation of an alkaline earth metal such as calcium ion or barium ion is generally used.

In the case where the polishing liquid contains equal to or more than a predetermined concentration of a metal ion, the discarding treatment that has been used is complicated, and in the case where the polishing liquid is designated as a deleterious substance because the polishing liquid contains the metal ion, it is not easy to handle the polishing liquid. Therefore, there is a demand of a user for using a polishing liquid containing no metal ion. In view of this, it is contemplated to use an organic salt which contains no metal and exhibits a basic property by hydrolysis, in place of a metal-containing inorganic salt which exhibits a basic property by hydrolysis. However, an aqueous solution containing only the organic salt dissolved therein is comparatively low in polishing rate, and there is a fear that a desired polishing rate cannot be realized. The present invention has been made in consideration of such a problem and provides a polishing liquid that is capable of enhancing a polishing rate, as compared to the case where an aqueous solution in which only an organic salt exhibiting a basic property by hydrolysis is dissolved is used as the polishing liquid, and that contains no metal.

In accordance with an aspect of the present invention, there is provided a polishing liquid that is used when one surface of a wafer is polished by use of a fixed abrasive grain polishing pad with abrasive grains fixed in the pad, in which an organic salt that exhibits a basic property by hydrolysis and contains no metal and an organic base that contains no metal are dissolved, and no abrasive grains are contained.

Preferably, the organic salt includes a strong basic cation and a weak acidic anion, and the organic base contains at least one of ammonia, an amine, and a basic amino acid.

In addition, preferably, the concentration of the organic salt is equal to or more than 0.50 wt %, and the concentration of the organic base is equal to or more than 0.025 wt %.

In the polishing liquid according one mode of the present invention, an organic salt that exhibits a basic property by hydrolysis and contains no metal and an organic base that contains no metal are dissolved. By the actions of the organic salt and the organic base, a polishing rate can be enhanced as compared to the case where an aqueous solution in which only an organic salt exhibiting a basic property by hydrolysis is dissolved is used as the polishing liquid. Further, since the polishing liquid contains no abrasive grains, there is a merit that the inside of the apparatus and the workpiece are not contaminated with the abrasive grains, unlike the case where free abrasive grains are used.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a sectional view depicting a general configuration of a polishing apparatus;

FIG. 2 is a graph depicting polishing rates in the case where the concentration of guanidine carbonate is variously set;

FIG. 3 is a graph depicting polishing rates in the case where the weight ratio of an organic base to an organic salt is variously set; and

FIG. 4 is a graph depicting transitions of polishing rates when five-minute polishing is repeated ten times.

### DETAILED DESCRIPTION OF THE PREFERRED EMBODIMENT

An embodiment according to a mode of the present invention will be described referring to the attached drawings. First, a polishing liquid to be used in the present embodiment will be described. Note that, in the present embodiment, it is assumed that a fixed abrasive grain polishing pad with abrasive grains fixed in the polishing pad is used. Therefore, as the polishing liquid to be used for the fixed abrasive grain polishing pad, a polishing liquid that contains no abrasive grains is used.

Incidentally, for using a polishing liquid containing no metal, it may be contemplated to use a polishing liquid in which only an organic salt that exhibits a basic property by hydrolysis and contains no metal is dissolved, but such a polishing liquid has the demerit of a comparatively low polishing rate. However, in the case where such a polishing liquid is used, although the polishing rate is comparatively low, the fixed abrasive grain polishing pad is less liable to be clogged with polishing swarf, so that there is a merit that a lowering in polishing rate (the thickness of the wafer removed per unit time) with time is less liable to Occur.

On the other hand, for enhancing a chemical etching effect as compared to the polishing liquid in which only the organic salt that exhibits a basic property by hydrolysis and contains no metal is dissolved, it may be contemplated to use a polishing liquid containing an organic base dissolved therein, in place of the polishing liquid containing only the organic salt dissolved therein. However, in the case of using a polishing liquid which contains no abrasive grains and in which only the organic base containing no metal is dissolved, as the polishing liquid to be used for the fixed abrasive grain polishing pad, the polishing swarf clogs up the pores of the fixed abrasive grain polishing pad, so that holding performance of the fixed abrasive grain polishing pad for holding the polishing liquid in the pad would be lowered. Therefore, a lowering in polishing rate with time is liable to occur.

In consideration of the foregoing, the present applicant has considered that, when the organic salt and the organic base described above are used together, it may be possible to compensate for the demerit of the organic salt by the merit of the organic base and to compensate for the demerit of the organic base by the merit of the organic salt. In other words, the present applicant has considered that use of the organic salt and the organic base together ensures that the polishing rate is higher than that in the case of using only the organic salt, and also ensures that a lowering in polishing rate with time is less liable to occur than the case of using only the organic base.

### (Polishing Liquid)

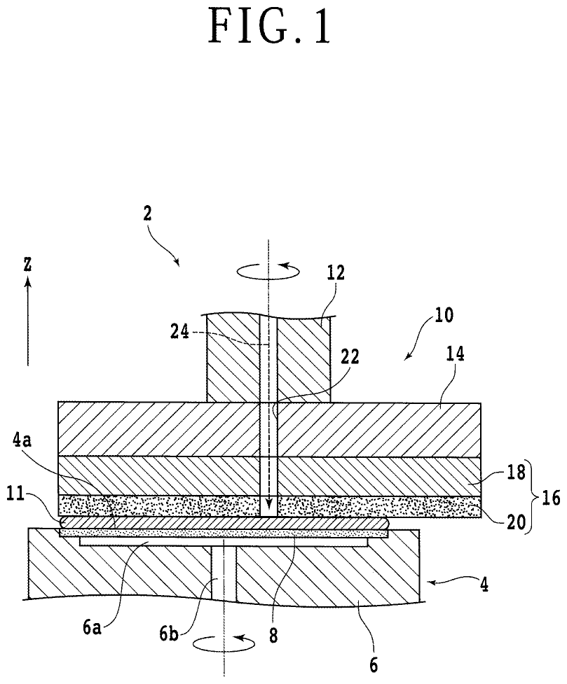

In the polishing liquid of the present embodiment, an organic salt exhibiting a basic property by hydrolysis in pure water and an organic base are dissolved, and no abrasive grains are contained. Note that both the organic salt and the organic base contain no metal. While details are described later, in a polishing liquid 24 (See FIG. 1), it is preferable that the amount of the organic salt is equal to or more than 0.50 wt % and that the amount of the organic base is equal to or more than 0.025 wt %. The organic salt is a water-soluble salt and includes a strong basic cation containing no metal and a weak acidic anion. As the strong basic cation, for example, an organic base containing a nitrogen atom is used. As the organic salt containing the nitrogen atom, for example, quinidine or a derivative thereof is used. In addition, as the weak acidic anion, an anion of carbonic acid, phosphoric acid, oxalic acid, acetic acid, formic acid, silicic acid, or the like is preferable.

The organic base includes at least one of ammonia, an amine, and a basic amino acid that exhibit a basic property in an aqueous solution. As the basic amino acid, for example, arginine, histidine, and lysine may be used. As the amine, for example, a water-soluble organic compound such as an aliphatic amine and a heterocyclic amine is used. As the aliphatic amine, ethylenediamine, propanediamine, butanediamine, pentanediamine, hexanediamine, diethylenetriamine, and tris(2-aminoethyl)amine may be used. In addition, as the heterocyclic amine, piperazine and imidazole may be used.

Next, an experiment for specifying the weight ratio between the organic salt and the organic base that is optimum for polishing will be described. In the experiment, a silicon wafer not formed with devices or the like (bare wafer) was polished by a polishing apparatus 2 (see FIG. 1). Here, an outline of the polishing apparatus 2 used in the experiment will be described. FIG. 1 is a sectional view depicting an outline of the polishing apparatus 2 of the face-up system for polishing an upper surface side of a wafer 11. Note that a Z-axis direction depicted in FIG. 1 is substantially parallel to the vertical direction. The polishing apparatus 2 has a disk-shaped chuck table 4.

An upper end portion of a cylindrical rotary shaft (not illustrated) disposed substantially in parallel to the Z-axis direction is connected to a lower portion of the chuck table 4. An output shaft of a rotational drive source (not illustrated) such as a motor is connected to a lower end portion of the rotary shaft. When the rotational drive source is operated, the chuck table 4 is rotated in a predetermined direction around the rotary shaft parallel to the Z-axis direction. The chuck table 4 has a disk-shaped frame body 6 formed of a metal such as stainless steel. An upper portion of the frame body 6 is formed with a disk-shaped recess, and a disk-shaped porous plate 8 formed of a porous ceramic or the like is fixed to the recess.

An upper surface of the porous plate 8 and an upper surface of the frame body 6 are flush with each other, to form a substantially flat holding surface 4a. A plurality of first flow channels 6a along the radial direction of the frame body 6 are formed in a portion of the frame body 6, where the portion locates under a lower side of the porous plate 8. Note that, in FIG. 1, one first flow channel 6a is depicted. In addition, in a central portion in the radial direction of the frame body 6, a second flow channel 6b is formed along the Z-axis direction. An upper end portion of the second flow channel 6b is connected to the first flow channels 6a, and a lower end portion of the second flow channel 6b is connected to a suction source (not illustrated) such as an ejector. When the suction source is operated, a negative pressure is transmitted to the upper surface of the porous plate 8.

The wafer 11 disposed on the holding surface 4a is held under suction by the negative pressure generated on the holding surface 4a. A polishing unit 10 is disposed above the holding surface 4a. The polishing unit 10 has a cylindrical spindle housing (not illustrated). A cylindrical spindle 12 is accommodated in the spindle housing in a rotatable manner. The longitudinal direction of the spindle 12 is set substantially parallel to the Z-axis direction. A motor (not illustrated) for rotating the spindle 12 is provided at an upper end portion of the spindle 12.

A central portion of an upper surface of a disk-shaped mount 14 is connected to a lower end portion of the spindle 12. The mount 14 has a diameter larger than the diameter of the wafer 11. A disk-shaped polishing wheel 16 substantially equal in diameter to the mount 14 is mounted to a lower surface of the mount 14. The polishing wheel 16 has a disk-shaped wheel base 18 connected to the lower surface of the mount 14. The wheel base 18 is formed of a metal such as aluminum or stainless steel. A polishing pad 20 substantially equal in diameter to the wheel base 18 is fixed to a lower surface of the wheel base 18.

The polishing pad 20 is a fixed abrasive grain polishing pad with abrasive grains fixed in the pad. The polishing pad 20 can be manufactured, for example, by impregnating a polyester-made nonwoven fabric with a urethane solution in which abrasive grains on the order of micrometers in size are dispersed, and then drying the fabric. The abrasive grains are formed of a material such as silica (silicon oxide), silicon carbide, cubic boron nitride (cBN), diamond, and metal oxide particulates. Examples of the metal oxide particulates for use as abrasive grains include ceria (cerium oxide), zirconia (zirconium oxide), and alumina (aluminum oxide).

Center positions of the polishing pad 20, the wheel base 18, the mount 14, and the spindle 12 in the radial direction are substantially coincident with each other, and a cylindrical through-hole 22 is formed such as to penetrate these center positions. A piping (not illustrated) of a polishing liquid supply source (not illustrated) is connected to an upper end portion of the through-hole 22. The polishing liquid supply source includes the piping, a liquid feed pump, a storage tank of the polishing liquid 24, and the like. The polishing liquid supply source supplies the polishing liquid 24 to a through opening of the polishing pad 20 through the through-hole 22. Note that the polishing liquid 24 contains no abrasive grains.

The use of the polishing liquid 24 containing no abrasive grains has the merit that the inside of the polishing apparatus 2 and the wafer 11 as a workpiece can be prevented from being contaminated with the abrasive grains, unlike the case of using a polishing liquid containing abrasive grains (namely, free abrasive grains). Note that a Z-axis direction moving unit (not illustrated) is connected to the spindle housing. By pushing the polishing unit 10 downward by the Z-axis direction moving unit, the polishing pad 20 can press downward, with a predetermined pressure, the wafer 11 held under suction by the holding surface 4a.

In polishing the wafer 11, first, the wafer 11 is held under suction by the holding surface 4a. Then, the chuck table 4 is rotated in a predetermined direction, and the spindle 12 is rotated in a predetermined direction. In this instance, when the polishing pad 20 is pressed downward with a predetermined pressure while the polishing liquid 24 is supplied from the polishing liquid supply source, the upper surface (a surface on one side) side of the wafer 11 is polished by a chemical action and a mechanical action on the upper surface side of the wafer 11 and a lower surface side of the polishing pad 20 including the polishing liquid 24.

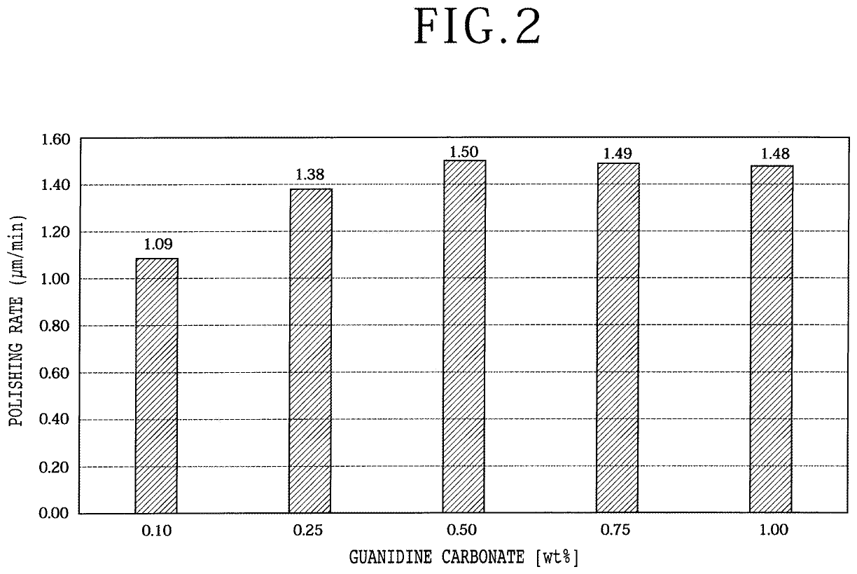

Next, an optimum concentration of the organic salt in the experiment will be described. FIG. 2 is a graph depicting polishing rates (μm/min) in the case where the concentration of guanidine carbonate was set to various values (0.10 wt %, 0.25 wt %, 0.50 wt %, 0.75 wt %, and 1.00 wt %). The bar graph depicts the polishing rate (μm/min) located at the left side of the axis of ordinates in FIG. 2. As the abrasive grains of the polishing pad 20, silica-made abrasive grains were used. In the experiment, the rotational speed of the spindle 12 was 500 rpm, and the rotational speed of the chuck table 4 was 505 rpm. In addition, the pressure on the wafer 11 was 25 kPa. As the polishing liquid, an aqueous guanidine carbonate solution that contained no abrasive grains and was obtained by dissolving powder-form guanidine in pure water was supplied from the polishing liquid supply source at a flow rate of 0.15 L/min. Besides, the polishing time was 300 seconds (namely, five minutes).

As depicted in FIG. 2, the polishing rate became substantially constant when the concentration of guanidine carbonate became equal to or more than 0.50 wt %. Therefore, the concentration of guanidine carbonate is preferably equal to or more than 0.50 wt %. However, it is to be noted that, in the case where the concentration is equal to or more than 0.50 wt %, the chemical agent cost is raised as the concentration of the guanidine carbonate is raised. Therefore, in the range of 0.10 to 1.00 wt %, it is preferable that the concentration of guanidine carbonate is in the range of equal to or more than 0.50 wt % and is closer to 0.50 wt %, for raising the polishing rate while the chemical agent cost is suppressed. Taking this result into account, next, polishing liquids 24 containing the organic salt (guanidine carbonate 0.50 wt %) and various concentrations of an organic base (1,3-propanediamine (hereinafter referred to simply as propanediamine)) were prepared, and difference in polishing rate in relation to the concentration of the organic base was examined.

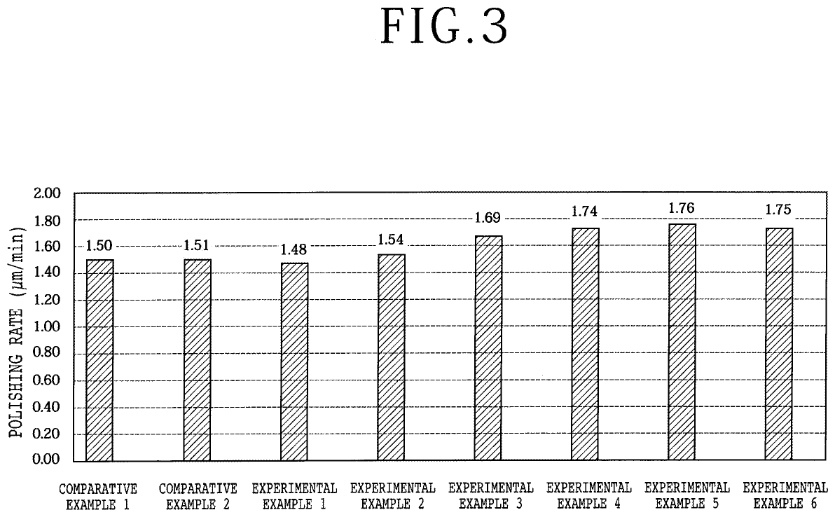

FIG. 3 is a graph depicting polishing rates in the case where the concentration (wt %) of the organic base (propanediamine) was changed in relation to the organic salt (guanidine carbonate). The axis of abscissas represents the kind of the polishing liquid as set forth in Table 1 below, and the axis of ordinates represents the polishing rate (μm/min) in the case of five-minute polishing. As the abrasive grains of the polishing pad 20, silica-made abrasive grains were used. In Comparative Examples 1 and 2 and Experimental Examples 1 to 6, the rotational speed of the spindle 12 was 500 rpm, and the rotational speed of the chuck table 4 was 505 rpm. In addition, the pressure on the wafer 11 was 25 kPa.

Comparative Example 1 is an experimental result in the case of polishing the wafer 11 while an aqueous base solution containing no abrasive grains and containing only 0.50 wt % of guanidine carbonate dissolved in pure water was supplied from the polishing liquid supply source at a flow rate of 0.15 L/min. Comparative Example 2 is an experimental result in the case of polishing the wafer 11 while an aqueous base solution containing no abrasive grains and containing only 0.10 wt % of propanediamine dissolved in pure water was supplied from the polishing liquid supply source at a flow rate of 0.15 L/min.

Experimental Examples 1 to 6 are experimental results in the cases of polishing the wafer 11 while an aqueous base solution (polishing liquid 24) containing no abrasive grains and containing guanidine carbonate and liquid propanediamine dissolved in pure water was supplied from the polishing liquid supply source at a flow rate of 0.15 L/min. Note that pH values of the polishing liquids 24 in Experimental Examples 1 to 6 are in the range of 10 to 14.

The concentrations (wt %) of guanidine carbonate, the concentrations (wt %) of propanediamine, and the polishing rates (μm/min) in the case of five-minute polishing, in Comparative Examples 1 and 2 and Experimental Examples 1 to 6 are set forth in Table 1.

TABLE 1

| | Guanidine | | Polishing rate upon |
|---|---|---|---|
| | carbonate | Propanediamine | five-minute polishing |
| | (wt %) | (wt %) | (μm/min) |
| Comparative | 0.50 | — | 1.50 |
| Example 1 | | | |
| Comparative | — | 0.10 | 1.51 |
| Example 2 | | | |
| Experimental | 0.50 | 0.010 | 1.48 |
| Example 1 | | | |
| Experimental | 0.50 | 0.025 | 1.54 |
| Example 2 | | | |
| Experimental | 0.50 | 0.050 | 1.69 |
| Example 3 | | | |
| Experimental | 0.50 | 0.10 | 1.74 |
| Example 4 | | | |
| Experimental | 0.50 | 0.25 | 1.76 |
| Example 5 | | | |
| Experimental | 0.50 | 0.50 | 1.75 |
| Example 6 | | | |

The polishing rates in Experimental Examples 2 to 6 are higher than the polishing rate in Comparative Example 1. Taking into account that, in the experiment depicted in FIG. 2, the polishing rate became substantially constant even when the concentration of guanidine carbonate was equal to or more than 0.50 wt %, it can be said that it is possible, by the actions of the organic salt and the predetermined concentration or more of the organic base, to enhance polishing rate as compared to the case where an aqueous solution exhibiting a basic property by hydrolysis and containing only the organic salt dissolved therein is used as the polishing liquid. In addition, the polishing rates in Experimental Examples 2 to 6 are higher than the polishing rate in Comparative Example 2. Therefore, it is preferable to set the concentration of propanediamine to 0.025 wt % or more.

However, it is to be noted that, since a rise in the concentration of propanediamine tends to increase the polishing rate, a concentration of the organic salt (guanidine carbonate) of equal to or more than 0.50 wt % and a concentration of the organic base (propanediamine) of equal to or more than 0.050 wt % may be adopted. Besides, a concentration of the organic salt of equal to or more than 0.50 wt % and a concentration of the organic base of equal to or more than 0.10 wt % may also be adopted, and a concentration of the organic salt of equal to or more than 0.50 wt % and a concentration of the organic base of equal to or more than 0.25 wt % may further be adopted.

Although a rise in the concentration of propanediamine tends to increase the polishing rate, a clear rising tendency in polishing rate is lost in Experimental Examples 4 to 6. Therefore, a concentration of the organic salt (guanidine carbonate) of equal to or more than 0.50 wt % and a concentration of the organic base (propanediamine) of equal to or more than 0.10 wt % are preferable. Particularly, for lowering the chemical agent cost and for enhancing the polishing rate, it is desirable to set the concentration of the organic base in the range of equal to or more than 0.10 wt % and close to 0.10 wt %.

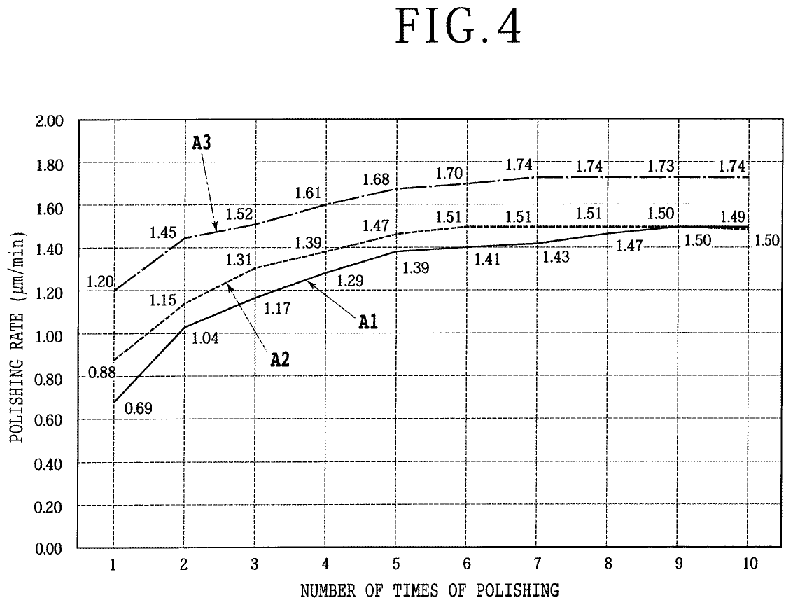

Next, it is investigated whether the use of the organic salt and the organic base makes it less likely to lower the polishing rate with time than the case where only the organic base is used. FIG. 4 is a line graph depicting the transitions of polishing rates when five-minute polishing is repeated ten times. The axis of ordinates represents the polishing rate (μm/min), and the axis of abscissas represents the number of times (one time to ten times). Note that one time of polishing is five minutes. A graph A1 (indicated by a solid line in FIG. 4) represents the transition of the polishing rate upon ten times of polishing in the case where the concentration of guanidine carbonate was 0.50 wt %. In addition, a graph A2 (indicated by a broken line in FIG. 4) represents the transition of the polishing rate upon ten times of polishing in the case where the concentration of propanediamine was 0.10 wt %.

Further, a graph A3 (indicated by an alternate long and short dash line in FIG. 4) represents the transition of the polishing rate upon ten times of polishing in the case where the concentration of guanidine carbonate was 0.50 wt % and the concentration of propanediamine was 0.10 wt %. In each time of polishing, the wafer 11 was polished under the same conditions as in the experiment of FIG. 3 (rotational speed of the spindle 12 of 500 rpm, rotational speed of the chuck table 4 of 505 rpm, pressure on the wafer of 25 kPa, supply amount of the polishing liquid of 0.15 L/min). The polishing rates in the graphs A1 to A3 are set forth in Table 2, though overlapping with the information of FIG. 4.

TABLE 2

| | | | Graph A3 |
|---|---|---|---|
| | Graph A1 | | Guanidine |
| | Guanidine | Graph A2 | carbonate 0.50 wt % |
| | carbonate | Propanediamine | and Propanediamine |
| | 0.50 wt % | 0.10 wt % | 0.10 wt % |
| Number | Polishing rate | Polishing rate | Polishing rate |
| of times | (μm/min) | (μm/min) | (μm/min) |
| 1 | 0.69 | 0.88 | 1.20 |
| 2 | 1.04 | 1.15 | 1.45 |
| 3 | 1.17 | 1.31 | 1.52 |
| 4 | 1.29 | 1.39 | 1.61 |
| 5 | 1.39 | 1.47 | 1.68 |
| 6 | 1.41 | 1.51 | 1.70 |
| 7 | 1.43 | 1.51 | 1.74 |
| 8 | 1.47 | 1.51 | 1.74 |
| 9 | 1.50 | 1.50 | 1.73 |
| 10 | 1.50 | 1.49 | 1.74 |

As is clear from FIG. 4 and Table 2, in the case of the graph A1 (guanidine carbonate 0.50 wt %), though the polishing rate is lower than that in the graphs A2 and A3, the polishing rate is not lowered upon ten times of polishing (namely, 5 minutes×10 times=50 minutes). In addition, the present applicant has confirmed that the polishing swarf adhering to the polishing pad 20 that has been used is considerably little in the case where the aqueous guanidine carbonate solution is used as the polishing liquid, by observation of the polishing pad 20 that has been used.

Adhesion of the polishing swarf is considered to be closely related to the polishing rate, and it is considered that a lowering in polishing rate with time is not generated in the graph A1 since the polishing pad 20 is less liable to be clogged. On the other hand, in the case of the graph A2 (propanediamine 0.10 wt %), though the polishing rate is generally higher than that in the graph A1, the polishing rate is substantially constant at the sixth to eighth times of polishing, and at the ninth and tenth times of polishing, the polishing rate is lowered as compared to the sixth to eighth times of polishing. In other words, a tendency that the polishing rate is lowered when polishing is repeated has been confirmed.

As described above, it is considered that the lowering in polishing rate with time as depicted in the graph A2 occurs because the polishing swarf clogs up the pores of the polishing pad 20 and the holding performance of the polishing pad 20 to hold the polishing liquid in the pad is thus lowered. In practice, the present applicant has confirmed that, in the case of using the aqueous propanediamine solution as the polishing liquid, the amount of the polishing swarf adhering to the polishing pad 20 that has been used is considerable as compared to the case where the aqueous guanidine carbonate solution is used as the polishing liquid.

In the case of the graph A3 (guanidine carbonate 0.50 wt % and propanediamine 0.10 wt %), the polishing rate is normally high as compared to the graph A2, and a lowering in polishing rate is not generated exclusive of the ninth time of polishing. In addition, the polishing rate upon the tenth times of polishing is higher than that upon the ninth time of polishing and is comparable to the value of the polishing rate upon the seventh time and the eighth time of polishing. In this way, by use of the organic salt and the organic base, it is possible to enhance the polishing rate as compared to the case of using only the organic salt, and to restrain a lowering in the polishing rate with time as compared to the case of using only the organic base.

Note that, while guanidine carbonate is used as the organic salt and propanediamine is used as the organic base in the experiment depicted in FIG. 4 and Table 2, it is conjectured that a similar effect can be obtained in the case where another organic salt considered to have an action similar to that of guanidine carbonate at the time of polishing and another organic base considered to have an action similar to that of propanediamine at the time of polishing are used. Other than the above, the structures, methods, and the like concerning the present embodiment can appropriately be modified insofar as the modifications do not depart from the scope of the object of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A polishing liquid that is used when one surface of a wafer is polished by use of a fixed abrasive grain polishing pad with abrasive grains fixed in the pad,
wherein an organic salt that exhibits a basic property by hydrolysis and contains no metal and an organic base that contains no metal are dissolved, and no abrasive grains are contained.

2. The polishing liquid according to claim 1,
wherein the organic salt includes a strong basic cation and a weak acidic anion, and
the organic base contains at least one of ammonia, an amine, and a basic amino acid.

3. The polishing liquid according to claim 1,
wherein a concentration of the organic salt is equal to or more than 0.50 wt %, and
a concentration of the organic base is equal to or more than 0.025 wt %.
